(19) United States
(12) Patent Application Publication
(10) Pub. No.: US 2013/0003771 A1
(43) Pub. Date: Jan. 3, 2013

(54) DISTRIBUTED FEEDBACK LASER DIODE HAVING ASYMMETRIC COUPLING COEFFICIENT AND MANUFACTURING METHOD THEREOF

(75) Inventors: Oh Kee KWON, Daejeon (KR); Young Ahn Leem, Daejeon (KR); Dong-Hun Lee, Daejeon (KR); Chul-Wook Lee, Daejeon (KR); Yongsoon Baek, Daejeon (KR); Yun C. Chung, Daejeon (KR)

(73) Assignee: ELECTRONICS AND TELECOMMUNICATIONS RESEARCH INSTITUTE, Daejeon (KR)

(21) Appl. No.: 13/482,247

(22) Filed: May 29, 2012

(30) Foreign Application Priority Data
Jul. 1, 2011 (KR) 10-2011-0065556

(51) Int. Cl. H01S 5/187; H01L 21/02

(52) U.S. Cl. 372/50.11; 438/31; 257/E21.002

(57) ABSTRACT

Provided are a distributed feedback laser diode and a manufacturing method thereof. The distributed feedback laser diode includes a first area having a first grating layer disposed in a longitudinal direction, a second area disposed adjacent to the first area and having a second grating layer disposed in the longitudinal direction, and an active layer disposed over the first and second areas. Coupling coefficients of the first and second grating layers are made different in the first and second areas by a selective area growth method. The distributed feedback laser diode includes grating layers each having an asymmetric coefficient and is implemented within an optimal range capable of obtaining both a high front facet output and stable single mode characteristics. Thus, high manufacturing yield and low manufacturing cost can be achieved.

### CROSS-REFERENCE TO RELATED APPLICATIONS

This US non-provisional patent application claims priority under 35 USC §119 to Korean Patent Application No. 10-2011-0065556, filed on Jul. 1, 2011, the entirety of which is hereby incorporated by reference.

### BACKGROUND OF THE INVENTION

The present general inventive concept relates to distributed feedback laser diodes having asymmetric coupling coefficient and manufacturing methods thereof.

After the first semiconductor laser diode was developed in the 1960s, semiconductor laser diodes with improved performance have been developed with the advance in optical communication technology and rapid advance in semiconductor fabrication process. In 1972, a distributed feedback laser diode (DFB-LD) capable of providing a longitudinal single mode was introduced and spotlighted as one of the promising light sources in optical communication system.

Due to the advantages such as small size, stable operation, and high reliability, a distributed feedback laser diode and its integrated forms have been used as key light sources for optical communication so far.

Although the required performances are slightly different according to uses in application systems, high efficiency (i.e., low operating current and high output power) and high single mode stability are basically and essentially required in single mode laser. Various types of developments have been reported to meet the requirements for performance.

### SUMMARY OF THE INVENTION

Embodiments of the inventive concept provide a distributed feedback laser diode and a method for manufacturing the same.

According to an aspect of the inventive concept, the distributed feedback laser diode may include a first area having a first grating layer disposed in a longitudinal direction, a second area disposed adjacent to the first area and having a second grating layer disposed in the longitudinal direction, and an active layer disposed over the first and second areas. Coupling coefficients of the first and second grating layers are made different in the first and second areas by a selective area growth method.

In some embodiments, wherein a phase of a diffraction grating is shifted by a quarter of an operation wavelength to perform a single longitudinal mode operation.

In some embodiments, the distributed feedback laser diode may further include a phase-shifted area formed between the first and second areas in the longitudinal direction to shift the phase of the diffraction grating by a quarter of the operation wavelength.

In some embodiments, the phase of the diffraction grating may be shifted by a quarter of the operation wavelength at a facet adjacent to the first and second areas.

In some embodiments, thicknesses the first and second grating layers may be different from each other.

In some embodiments, a ratio of the thicknesses of the first and second grating layers may rapidly vary above 1.7 times at the adjacent facet.

In some embodiments, a ratio of the thicknesses of the first and second grating layers may gently vary below 1.7 times at the adjacent facet.

In some embodiments, a thickness between the active layer and the first grating layer may be different from that between the active layer and the second grating layer.

In some embodiments, lengths of the first and second areas may equal to each other in the longitudinal direction, and the first and second grating layers may have the same grating shape.

In some embodiments, a ratio of a coupling coefficient of the second grating layer to a coupling coefficient of the first grating layer may range from 0.6 to 1.

In some embodiments, the first area may have a first facet differing from the facet adjacent to the first and second areas, and the distributed feedback laser diode may further include a high reflection layer coated on the first facet of the first area.

In some embodiments, the second area may have a second facet differing from the adjacent facet, and the distributed feedback laser diode may further include an anti-reflection layer coated on the second facet of the second area.

According to another aspect of the inventive concept, the method may include forming a first grating layer and a second grating layer by a selective area growth method, forming a spacer layer on the first and second grating layers, forming a clad layer on the spacer layer, and forming an ohmic layer on the clad layer. The first and second grating layers are disposed adjacent to each other and have different coupling coefficients.

In some embodiments, the forming of the first and second grating layers may include making thicknesses of the first and second grating layers different from each other.

In some embodiments, the thicknesses of the first and second grating layers may be varied by adjusting a width of an open area at a mask.

In some embodiments, the thicknesses of the first and second grating layers may be varied by adjusting a width of a mask.

In some embodiments, the forming of the spacer layer may include making a thickness between the first grating layer and the active layer and a thickness between the second grating layer and the active layer different from each other.

In some embodiments, a width of a mask may be adjusted to rapidly vary coupling coefficients of the first and second grating layers.

In some embodiments, a mask may be tapered to gently vary coupling coefficients of the first and second grating layers.

In some embodiments, after forming an ohmic layer, the method may further include forming a ridge waveguide.

### BRIEF DESCRIPTION OF THE DRAWINGS

The inventive concept will become more apparent in view of the attached drawings and accompanying detailed description. The embodiments depicted therein are provided by way of example, not by way of limitation, wherein like reference numerals refer to the same or similar elements. The drawings are not necessarily to scale, emphasis instead being placed upon illustrating aspects of the inventive concept.

FIG. 1 is a cross-sectional view of a typical asymmetric coupling coefficient distributed feedback laser diode in a longitudinal direction.

FIGS. 2 and 3 are graphic diagrams illustrating results of distributions of photon density and carrier density in a cavity length direction according to change of a coupling coefficient ratio when current above threshold current is injected to a structure where a cavity length is 400 μm and a normalized coupling coefficient of a first area is 2.2, respectively.

FIGS. 4 and 5 are graphic diagrams illustrating a front facet power and a normalized threshold gain difference according to the current injected to the asymmetric coupling coefficient distributed feedback laser diode shown in FIG. 1, respectively.

FIGS. 6 and 7 are graphic diagrams illustrating a normalized threshold gain difference and a front facet power relative to a normalized coupling coefficient of a first area and a normalized coupling coefficient of a second area when injected current is 100 mA, respectively.

FIGS. 8 and 9 are graphic diagrams illustrating a normalized threshold gain difference and a front facet power, depending on increase in the normalized coupling coefficient of the first area, relative to a symmetric grating (SG) and an optimized asymmetric coupling coefficient feedback laser diode, respectively.

FIGS. 10 and 11 are graphic diagrams illustrating an optical output ratio and a coupling coefficient ratio, depending on change of a normalized coupling coefficient of a first area, relative to a structure where the maximum normalized threshold gain difference is obtained and a structure where a normalized threshold gain difference of 0.3 is obtained, respectively.

FIG. 12 is a cross-sectional view of an asymmetric coupling coefficient distributed feedback laser diode according to a first embodiment of the inventive concept.

FIG. 13 is a cross-sectional view of an asymmetric coupling coefficient distributed feedback laser diode according to a second embodiment of the inventive concept.

FIG. 14 is a cross-sectional view of an asymmetric coupling coefficient distributed feedback laser diode according to a third embodiment of the inventive concept.

FIG. 15 is a cross-sectional view of an asymmetric coupling coefficient distributed feedback laser diode according to a fourth embodiment of the inventive concept.

FIG. 16 is a graphic diagram illustrating an analysis result of a grating coupling coefficient, depending on change in a thickness of a diffraction grating and change in a thickness of a spacer, relative to a grating layer material structure that is an InGaAsP structure and a spacer layer material structure that is an InP material structure, in the form of a ridge waveguide which includes a multi-quantum well structure where a gain wavelength peak of an active layer is 1300 nm in the InGaAsP material structure and has a width of 2.2 μm.

FIG. 17 is a graphic diagram illustrating an analysis result of growth rate enhancement obtained by solving a Laplace equation to indium (In) and gallium (Ga), which are III group materials, using a mask having a width of 100 μm when a width of an open area is 100 μm.

FIGS. 18 and 19 are graphic diagrams illustrating analysis results of growth rate enhancements when bandgap wavelengths of an InGaAsP material relative to a mask having a width of 100 μm are 1.15 μm, 1.2 μm, and 1.36 μm depending on change in width of an open area relative to an InP material.

### DETAILED DESCRIPTION

The inventive concept will now be described more fully hereinafter with reference to the accompanying drawings, in which preferred embodiments of the inventive concept are shown.

A distributed feedback laser diode (DFB-LD) according to an embodiment of the inventive concept has diffraction gratings of coupling coefficients varying depending on areas in a cavity. For example, a distributed feedback laser diode (DFB-LD) according to an embodiment of the inventive concept may includes a cavity whose first area implemented by a first diffraction grating having a relatively higher coupling coefficient and second area implemented by a second diffraction grating having a relatively lower coupling coefficient to increase an optical output of one surface. Thus, a high optical output may be obtained at a cross section implemented by the second diffraction grating having a relatively lower coupling coefficient.

A distributed feedback laser diode (DFB-LD) according to an embodiment of the inventive concept is allowed to achieve a diffraction grating having coupling coefficients varying depending on areas. For this, in the form of gratings having the same period and shape, a thickness of a grating layer is changed or a space layer between an active area and a grating layer is changed by means of selective area growth (SAG).

The inventive concept presents an optimal range that makes it possible to obtain a high front facet output as well as stable single mode characteristic in a distributed feedback laser diode (DFB-LD). Thus, a distributed feedback laser diode (DFB-LD) according to an embodiment of the inventive concept is allowed to achieve higher manufacturing yield and lower manufacturing cost than a conventional DFB-LD.

A distributed feedback diode (DFB-LD) according to an embodiment of the inventive concept is a λ/4 phase-shifted DFB-LD (λ being an operating wavelength). In the λ/4 phase-shifted DFB-LD, a phase of a diffraction grating in a laser cavity is shifted by λ/4 to match a phase of reflectivity formed by the diffraction grating at a specific wavelength. Thus, the λ/4 phase-shifted DFB-LD is implemented to perform a single longitudinal mode (SLM) operation.

The λ/4 phase-shifted DFB-LD suffers from disadvantages that high single mode characteristics are exhibited in a structure having both front facets coated with an anti-reflection (AR) dielectric film and a single mode yield is rapidly reduced when front facet reflectivity increases. Moreover, in case of a structure where a phase shift (PS) area is disposed in the center (hereinafter referred to as “symmetric grating (SG)”), optical outputs of both the front facets are similarly obtained (practically, an optical output slightly varies depending on reflectivity of a front facet and a phase of a diffraction grating of the front facet). For this reason, it is difficult to efficiently use output light.

When a structure of moving a phase shift (PS) area to an information-transmitting front facet, i.e., an asymmetric phase shift (APS) structure is applied to a symmetric grating (SG), an optical output of the front facet significantly increases while single mode yield rapidly decreases, which is disclosed in “Asymmetric λ/4-shifted InGaAsP/InP DFB lasers” (IEEE J. Quant μm Electron., vol. QE-24, pp. 815-821, 1987.) by Usami et al. and Avago Technologies Fiber IP (Singapore) Pte. Ltd. (US 2010/0290489 A1, Nov. 18, 2010). As a result, it is substantially difficult to obtain a high optical output while meeting required single mode characteristics.

Without introduction of a phase shift (PS) area, one front facet of a distributed feedback laser diode (DFB-LD) is subjected to high reflection (HR) coating and the other front facet thereof is subjected to anti-reflection (AR) coating. Thus, reflectivity of the respective front facets may be optimized to improve longitudinal single mode characteristics at a specific wavelength and increase an optical output emitted to the AR-coated facet. This structure is advantageous in ease of process. However, single mode yield rapidly decreases due to random characteristics of a diffraction grating phase on the HR-coated facet (i.e., since a period of the diffraction grating is determined by an operation wavelength and is typically 200-250 nm at a wavelength band of 1300-1550 nm and an error of processes for forming a device length (e.g., processes for forming the total length of the diffraction grating through scribing or lithography and etching processes) is μm-order, it is not possible to accurately estimate a practical diffraction grating of the front facet). For this reason, devices for estimation and verification are verified one by one to cause the cost of the respective devices to increase.

The performance of a distributed feedback laser diode (DFB-LD) significantly varies depending on a coupling coefficient of a diffraction grating. Generally, in case of a structure with a high coupling coefficient (expressed by a normalized coupling coefficient (multiplication of a grating coupling coefficient by a cavity length) and corresponds to 3 or greater), single mode characteristics are significantly degraded due to non-uniform carrier density across the laser cavity (generally, represented as longitudinal spatial hole burning (LSHB)).

The above problem may be overcome by introducing structures (2×λ/8 and 3×λ/4) including a plurality of phase change (PS) areas. However, the structures are not widely used due to their complexity and decrease in single mode yield at low current. Both high efficiency and high single mode stability may be achieved in a distributed reflector-laser diode (DR-LD) and a distributed coupling efficient (DCC) DFB-LD. The distributed reflector-laser diode (DR-LD) is a laser diode in which a passing waveguide area including a diffraction grating with a high coupling coefficient is integrated into a partial area of a cavity and an active area is formed to makes carrier density relatively equal. The distributed coupling coefficient (DCC) DFB-LD is a laser diode in which a coupling coefficient of a diffraction grating varies at the center and the edge of a cavity to suppress longitudinal spatial hole burning (LSHB).

With reference to “Lasing Characteristics of 1.5 μm GaInAsP—InP SCH-BIG-DR Lasers” (IEEE J. Quant μm Electron., vol. 27, pp. 1736-1745, 1991) by J. I. Shim et al., in case of a distributed reflector-laser diode (DR-LD), monolithic integration of an active area and a passive area is required and a coupling coefficient of the passive area is about three times greater than that of the active area to obtain stable single mode characteristics. In addition, with reference to “HR-AR coated DFB Lasers with High-Yield and Enhanced Above-Threshold Performance” (Optics & Laser Tech., vol. 43, pp. 729-735, 2011) by J. B. M. Boavida et al., in case of a distributed coupling efficient (DCC) DFB-LD, a coupling coefficient of the edge of a diffraction grating is required to be at least eight times larger than that of the center of the diffraction grating.

In the above-described structures, a thick grating layer is grown. After a first diffraction grating is formed throughout a cavity, an area except for a specific area is masked to make coupling coefficient of the specific area different. And then, an etching process is performed. These steps are carried out to make a coupling coefficient of the diffraction grating different in a length direction (in other word, longitudinal direction) of the cavity. This manufacturing method is complex and disadvantageous in terms of device yield and reproducibility (a period of a diffraction grating is 200-250 nm, and a masking error caused by lithography is ˜μm).

Unlike the above-described structures, methods for implementing an asymmetric coupling coefficient (ACC) diffraction grating are disclosed in “Uncooled Directly Modulated 1.3 μm AlGaInAs-MQW DFB Laser Diodes” (Proc. of SPIE vol. 5595, pp. 228-233, 2004) by Aoyagi et al. and U.S. Pat. No. 7,277,465 B2 (Oct. 2, 2007) by T. Aoyagi et al. According to the methods, in a λ/4 PS-DFB LD, a duty cycle of a diffraction grating is made different left and right of a phase shift (PS) area, a thickness of a grating layer in a specific area is made different by selective etching or a space layer between a grating layer and an active layer is made different. Thus, the ACC diffraction grating has coupling efficiency varying depending on areas.

In the “Uncooled Directly Modulated 1.3 μm AlGaInAs-MQW DFB Laser Diodes” by Aoyagi et al., it is reported that an optical output ratio is 2.2 times and a side-mode suppression ration (SMSR) is about 50 dB at a λ/4 PS-DFB LD in which a coupling coefficient ratio (a ratio of a grating coupling coefficient of a front facet to a grating coupling coefficient of a rear facet) is about 0.77 (˜135 cm⁻¹/175 cm⁻¹).

The method of making a duty cycle different to implement an ACC structure, disclosed in the “Uncooled Directly Modulated 1.3 μm AlGaInAs-MQW DFB Laser Diodes” by Aoyagi et al., suffers from the disadvantage that diffraction characteristics are rapidly degraded when a diffraction grating with a duty cycle of 0.2 or less is formed by a conventional etching apparatus (i.e., the disadvantage that change of a coupling coefficient is not linear to change of duty-cycle). For this reason, it is determined that manufacturing yield is low in terms of reproducibility. Moreover, the ACC structure is implemented only by a high-cost apparatus such as an E-beam device.

The method of implanting an asymmetric coupling coefficient (ACC) structure using selective etching, disclosed in U.S. Pat. No. 7,277,465 B2 by T. Aoyagi et al., includes making a portion of an area in which a grating layer or a spacer layer is formed and performing a selective etching process. However, the method encounters disadvantages such as misalignment between the masked portion and a diffraction grating pattern, surface contamination and etching non-uniformity that occur during the etching, which may have an adverse effect on device performance.

In the “Uncooled Directly Modulated 1.3 μm AlGaInAs-MQW DFB Laser Diodes” (Proc. of SPIE vol. 5595, pp. 228-233, 2004) by Aoyagi et al. and U.S. Pat. No. 7,277,465 B2 (Oct. 2, 2007) by T. Aoyagi et al., only a test result of device performance after manufacturing and a manufacturing method are disclosed. However, a cause allowing an asymmetric coupling coefficient (ACC) structure to obtain higher optical output efficiency and higher single mode than a conventional symmetric grating (SG) structure and an optimized area for structural parameters causing asymmetry are not disclosed therein.

To sum up, a conventional symmetric grating phase-shifted distributed feedback laser diode (SG PS DFB-LD) is disadvantageous in low output efficiency because lights emitted to both front facets are similar in intensity. A distributed reflector-laser diode (DR-LD) and a distributed coupling coefficient distributed feedback laser diode (DCC DFB-LD) with improved optical output efficiency and single mode characteristics are disadvantageous in low device manufacturing yield. When an asymmetric phase-shifted (APS) DFB-LD is introduced, high optical efficiency is exhibited while single mode characteristics are rapidly degraded. However, an asymmetric coupling coefficient distributed feedback laser diode (ACC DFB-LD) may improve optical output efficiency and single mode characteristics.

According to a conventional method of implementing an asymmetric coupling coefficient distributed feedback laser diode (ACC DFB-LD), duty cycle of a diffraction grating is made different in a longitudinal partial area or a thickness of a grating layer or a spacer layer is made different by a selective etching process. The manner of making duty cycle different suffers from low manufacturing yield and a need for a high-cost apparatus such as an E-beam device because change of a coupling coefficient based on change of duty cycle is not linear. In order to form grating layers or spacer layers having different a thicknesses, a structure is implemented by masking a longitudinal partial area and performing an etching process. However, the structure encounters disadvantages such as misalignment between the masked portion and a diffraction grating pattern, surface contamination and etching non-uniformity that occur during the etching, which may have an adverse effect on device performance.

A conventional asymmetric coupling coefficient phase-shifted distributed feedback laser diode (ACC PS DFB-LD) may achieve both higher output efficiency and higher single mode than a symmetric grating phase-shifted distributed feedback laser diode (SG PS DFB-LD). Nonetheless, the ACC PS DFB-LD has disadvantages such as unreported cause and structural parameters, a reproducibility problem occurred in a conventional method of making duty cycle varied depending on areas, implementation only using a high-cost apparatus, and misalignment, surface contamination, and etching non-uniformity which may occur when being implemented by an etching process through masking.

Below, there will be described a detailed structure which may obtain both a high front facet output and stable single mode characteristics through device analysis on an asymmetric coupling coefficient distributed feedback laser diode (ACC DFB-LD). Additionally, there will be described a structure and a manufacturing method of the same which may overcome disadvantages such as low manufacturing yield and high manufacturing cost of a conventional structure. In the present inventive concept, there was examined the effect of coupling coefficient asymmetry on threshold characteristics of a device in a phase-shifted distributed feedback laser diode (PS DFB-LD). For the analysis on device performance, the analysis was conducted based on an analysis method disclosed in “Distributed feedback laser diodes and optical tunable filters” (John Wiley & Sons Ltd, England, 2003) by H. Ghafouri-Shiraz.

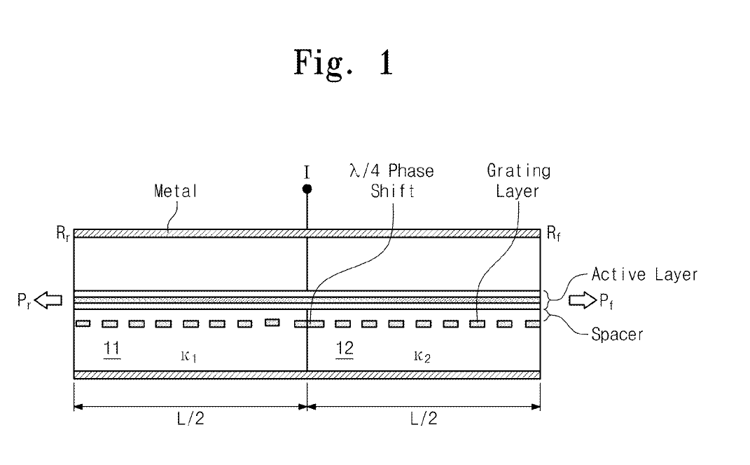

FIG. 1 is a cross-sectional view of a typical asymmetric coupling coefficient distributed feedback laser diode (ACC DFB-LD) in a longitudinal direction (cavity length direction). In FIG. 1, I represents injected current; L represents the overall length of a cavity; κ₁ and κ₂, represent grating coupling coefficients of a first area in a rear facet direction and a second area in a front facet direction at a λ/4 phase-shifted (PS) point, respectively; Pᵣ and P_{f} represent optical outputs of a rear facet and a front facet, respectively; and Rᵣ and R_{f} represent power reflectivities of the rear facet and the front facet, respectively. There is a spacer between an active layer and a diffraction grating.

Hereinafter, in an asymmetric coupling coefficient distributed feedback laser diode (ACC DFB-LD), a ratio of κ₂ to κ₁ will be referred to as a coupling coefficient ratio that is expressed by r_{κ}(=₂/₁). When r_{κ}=1, it corresponds to a symmetric structure. When r_{κ} decreases, coupling coefficients in respective areas may become asymmetrical gradually.

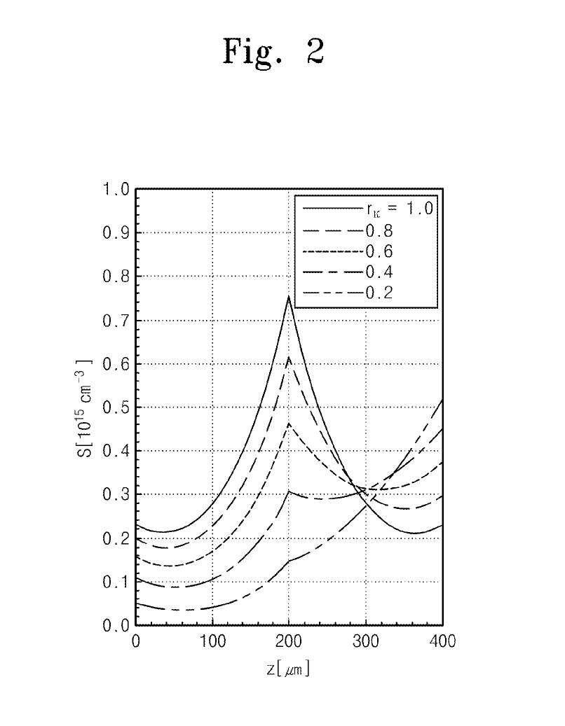

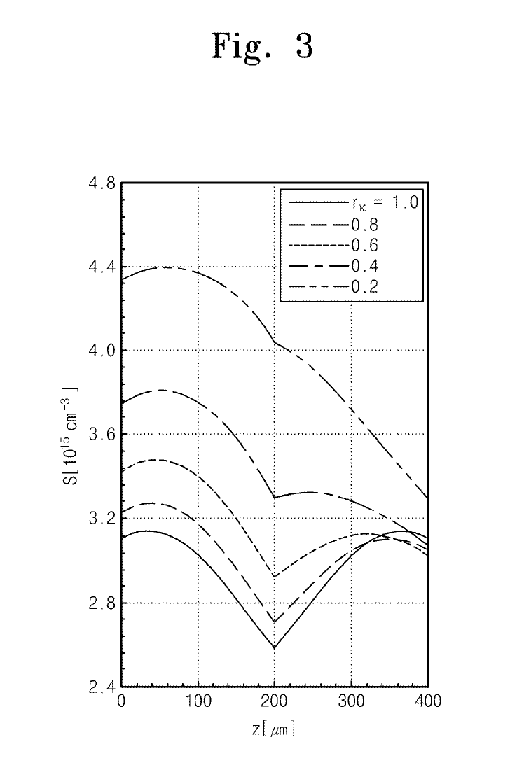

FIGS. 2 and 3 are graphic diagrams illustrating analysis results of distributions of photon density S and carrier density N in a longitudinal direction (cavity length direction) according to change of a coupling coefficient ratio r_{κ} when current (Iₜₕ+20 mA) above threshold current Iₜₕ is injected to a structure where a cavity length is 400 μm and a normalized coupling coefficient of a first area 11 is 2.2, respectively. Referring to FIGS. 2 and 3, the photon density S in a cavity becomes asymmetrical gradually with the decrease in the coupling coefficient ratio r_{κ}. Accordingly, high photon density S is exposed in a front facet direction and thus the carrier density N changes. For example, the carrier density N decreases because the higher the photon density S, the more carriers are consumed.

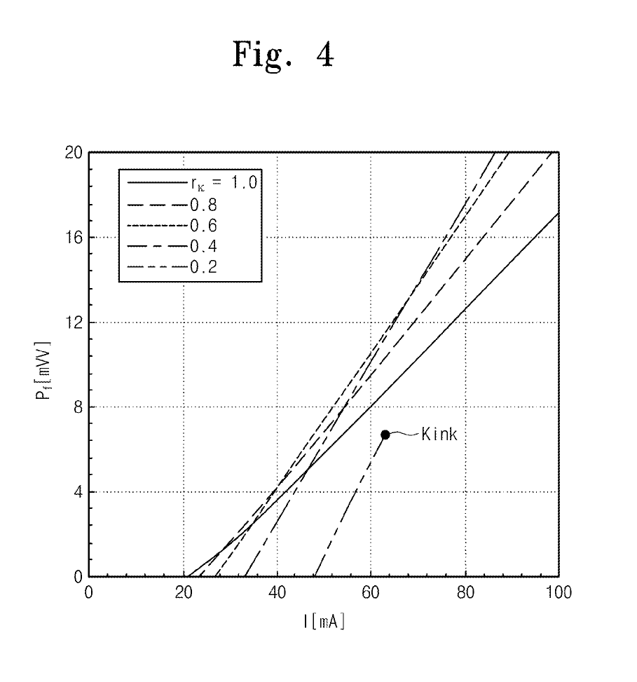

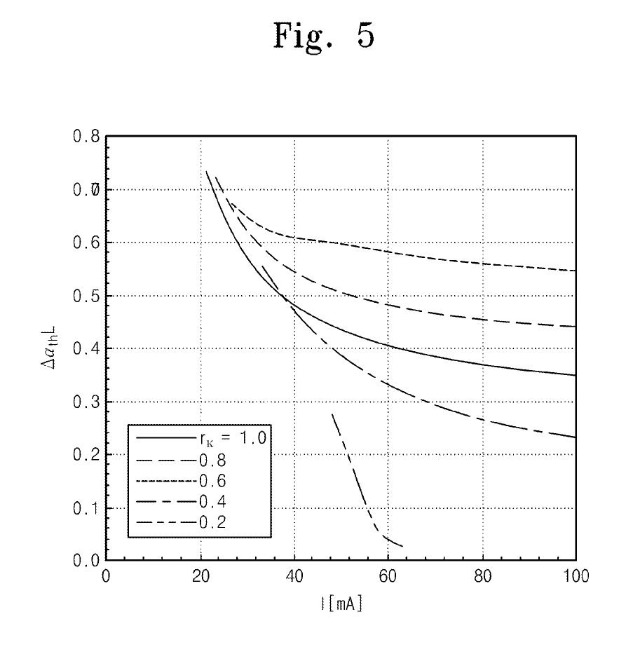

FIGS. 4 and 5 are graphic diagrams illustrating a front facet power P_{f} and a normalized threshold gain difference ΔαₜₕL between the main mode and side mode (ΔαₜₕL being a kind of parameter showing single mode characteristic) according to the current I injected to the asymmetric coupling coefficient distributed feedback laser diode (ACC DFB-LD) shown in FIG. 1, respectively. A side mode suppression ratio (SMSR) of about 25 dB may be obtained when a normalized threshold gain is about 0.2 (cavity length is 400 μm).

As shown in FIG. 4, a front facet optical output increases when a coupling coefficient ratio r, decreases. Meanwhile, as shown in FIG. 5, a normalized threshold gain is near 0 (mode competition between main and side modes is shown) when a coupling coefficient ratio r_{κ} is near 0.2 and thus unstable characteristics such as kink are exhibited in the current-optical output relationship. Accordingly, it could be understood that single mode characteristics are degraded when the coupling coefficient ratio r_{κ} is excessively low. In an analysis structure, the highest ΔαₜₕL is obtained when the coupling coefficient ratio r_{κ} is near 0.6. This is because a deviation of the carrier density N is smallest in the longitudinal direction (cavity length direction) when the coupling coefficient ratio r, is about 0.6, as can be seen in FIG. 3. Namely, this means that longitudinal spatial hole burning (LSHB) is least. In conclusion, the single mode characteristics are improved within a specific range of the coupling coefficient ratio r_{κ} (0.6≦r_{κ}<1) in the asymmetric coupling coefficient (ACC) structure.

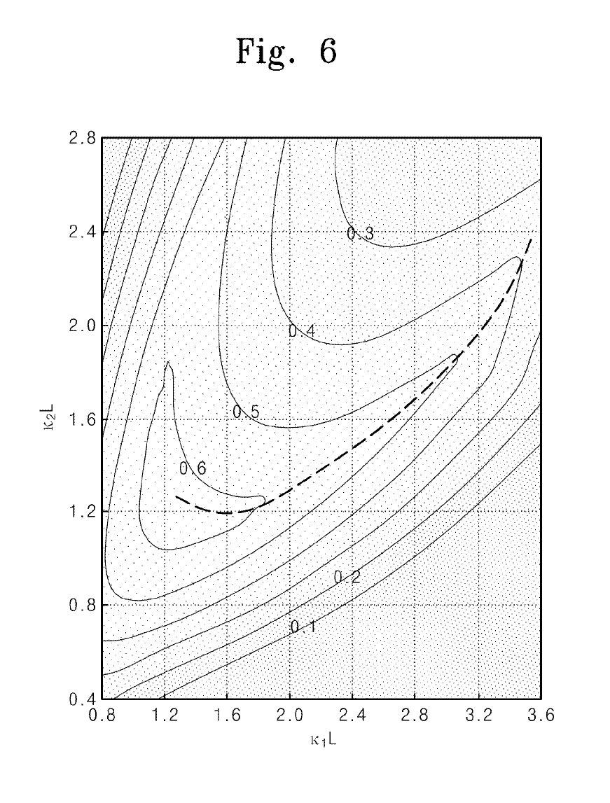

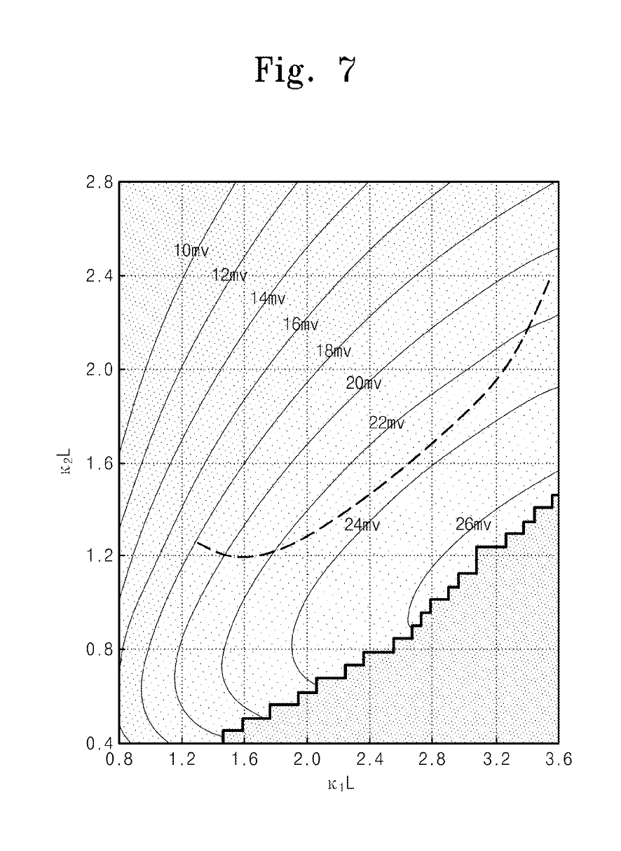

FIGS. 6 and 7 are graphic diagrams illustrating a normalized threshold gain difference ΔαₜₕL and a front facet power P_{f} relative to a normalized coupling coefficient κ₁L of a first area 11 and a normalized coupling coefficient κ₂L of a second area 12 when injected current I is 100 mA, respectively. In FIGS. 6 and 7, each dotted line represents the trace of κ₁₂L where the maximum ΔαₜₕL appears with the increase in κ₁L.

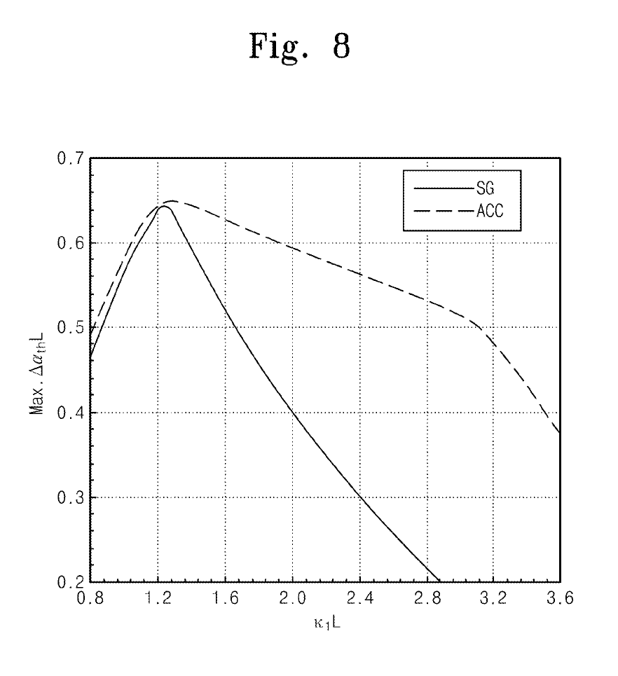

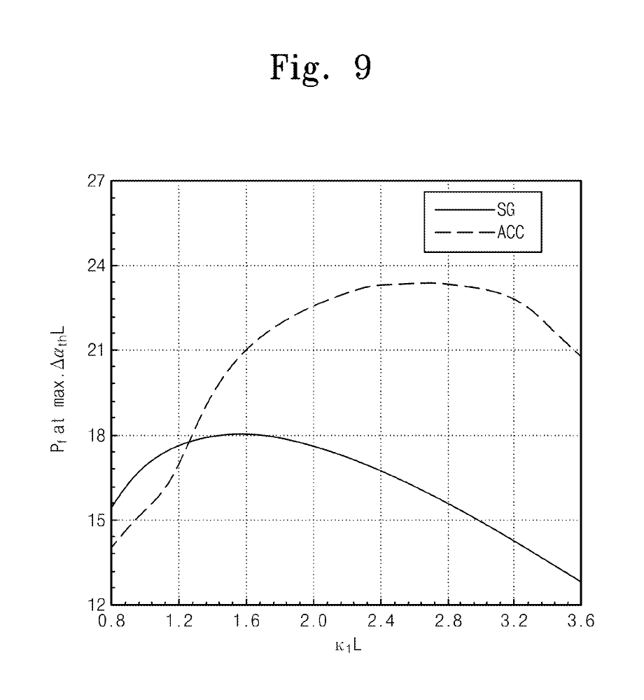

FIGS. 8 and 9 are graphic diagrams illustrating a normalized threshold gain difference ΔαₜₕL and a front facet power P_{f}, depending on increase in the normalized coupling coefficient κ₁L of the first area (κ₁L=κ₂L, in a symmetric grating (SG)), relative to the symmetric grating (SG) and an optimized asymmetric coupling coefficient feedback laser diode (ACC DFB-LD), respectively. As shown in FIGS. 8 and 9, performance improvement of an asymmetric coupling coefficient (ACC) structure is more obvious than that of a symmetric grating (SG) structure.

In the asymmetric coupling coefficient (ACC) structure, the front facet power P_{f} varies depending on the normalized threshold gain difference ΔαₜₕL.

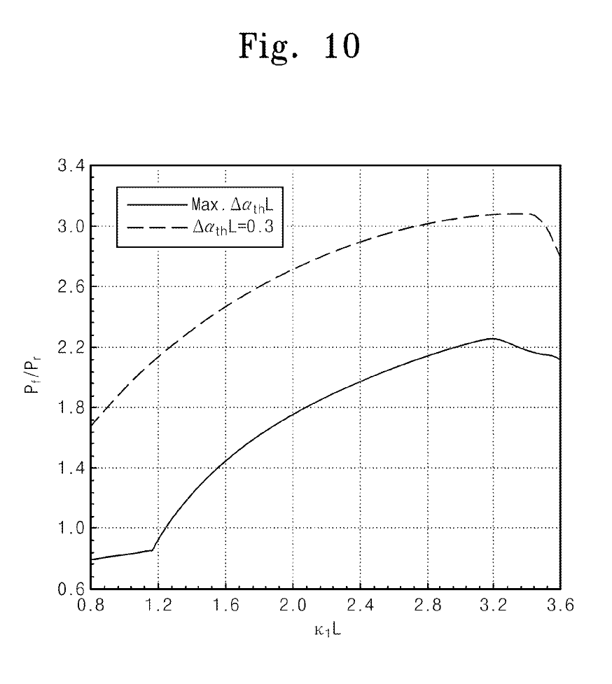

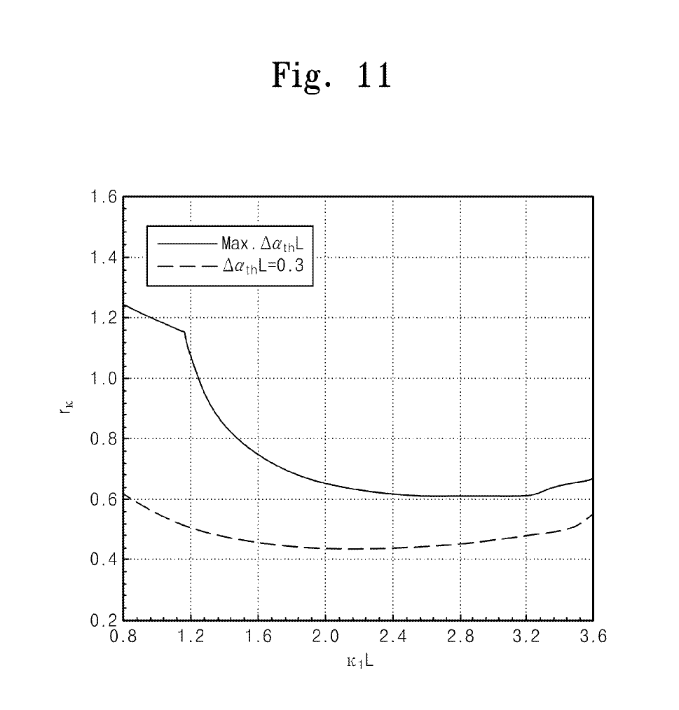

FIGS. 10 and 11 are graphic diagrams illustrating an optical output ratio P_{f}/Pᵣ and a coupling coefficient ratio r_{κ}, depending on change of the normalized coupling coefficient κ₁L of the first area, relative to a structure where the maximum normalized threshold gain difference ΔαₜₕL is obtained and a structure where a normalized threshold gain difference ΔαₜₕL of 0.3 is obtained, respectively. Referring to FIGS. 10 and 11, about 2.2 times optical output ratio (r_{κ} corresponds to about 0.6) may be obtained relative to the structure where the maximum ΔαₜₕL is obtained, and maximum three times optical output ratio (r_{κ}=0.5) may be obtained relative to the structure where the ΔαₜₕL is 0.3.

In the foregoing analysis, device-constituting material parameters and structural parameters are expressed by values commonly used by those skilled in the art relative to a distributed feedback laser diode (DFB-LD) in a 1.3 μm operation wavelength area based on InP/InGaAsP. An optimized value and a quantitative value of the analysis result may vary depending upon change in material, operation wavelength, and structure. Therefore, it could be confirmed that due to decrease in longitudinal spatial hole burning (LSHB), both higher single mode characteristics and a higher optical output (efficiency) may be obtained in an asymmetric coupling coefficient (ACC) structure than in a symmetric grating (SG) structure. Note that the higher characteristics and efficiency are not limited to specific values.

Asymmetric coupling coefficient distributed feedback laser diode (ACC DFB-LD) structures according to embodiments of the inventive concept will now be described below in detail.

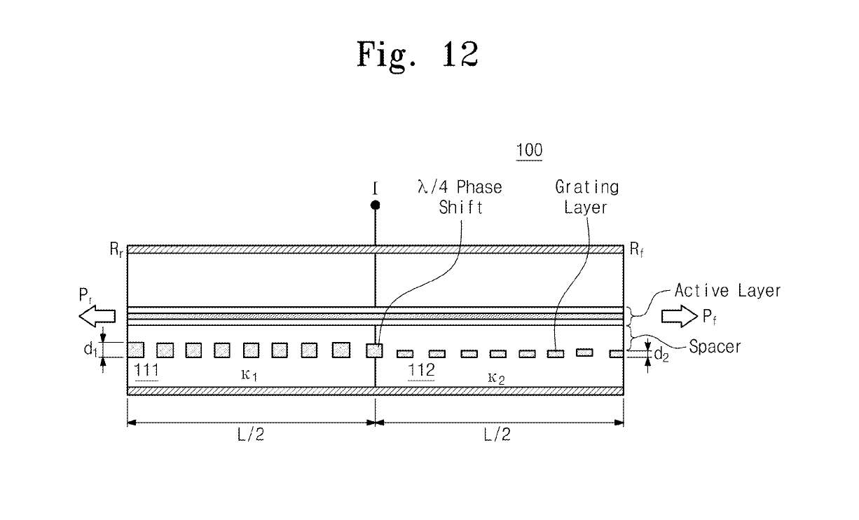

FIG. 12 is a cross-sectional view of an asymmetric coupling coefficient distributed feedback laser diode (hereinafter referred to as “ACC DFB-LD”) 100 according to a first embodiment of the inventive concept. In the ACC DFB-LD 100, a thicknesses d₁ and d₂ of a grating layer in first and second areas 111 and 112 formed in a longitudinal direction (cavity length direction) are made different from each other.

In the ACC DFB-LD 100, a coupling coefficient varies due to a thickness difference (d₁-d₂) of the grating layer in the first area 111 and the second area 112. In some embodiments, the thickness difference (d₁-d₂) of the grating layer may rapidly vary near a phase-shifted (PS) point (λ/4 phase shift), as shown in FIG. 12. For example, the first a thickness d₁ may be at least 1.7 times greater than the second a thickness d₂. In other embodiments, the thickness difference (d₁-d₂) of the grating layer may gently vary near the phase-shifted (PS) point (λ/4 phase shift). For example, the first a thickness d₁ may be less than 1.7 times the second a thickness d₂.

In some embodiments, the ACC DFB-LD 100 may further include a high reflection layer (not shown) coated on one surface of the first area 111, not a surface adjacent to the first area 111 and the second area 112.

In some embodiments, the ACC DFB-LD 100 may further include an anti-reflection layer (not shown) coated on one surface of the second area 112, not an adjacent surface.

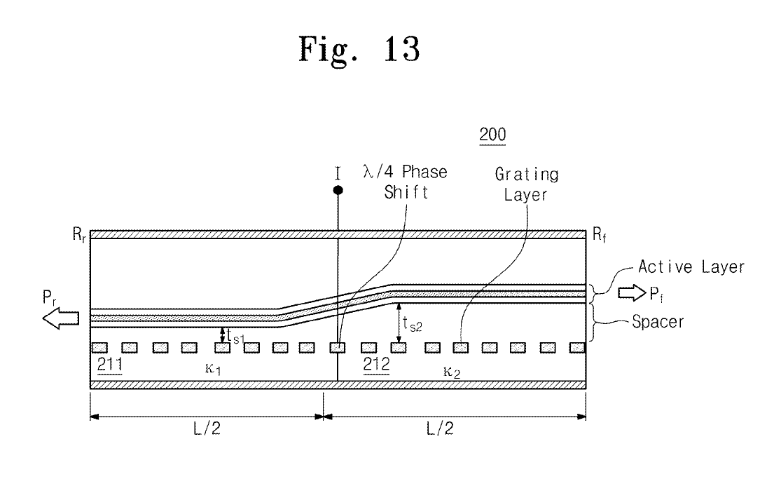

FIG. 13 is a cross-sectional view of an ACC DFB-LD 200 according to a second embodiment of the inventive concept. In the ACC DFB-LD 200, spacer a thicknesses tₛ₁ and tₛ₂ (the spacer a thickness being a thickness between a grating layer and an active layer) are made different from in a first area 211 and a second area 212 formed in a longitudinal direction (cavity length direction). In the ACC DFB-LD 200, a coupling coefficient varies due to a thickness difference (t_{S1}−t_{S2}) of the spacer in the first area 111 and the second area 112. In some embodiments, the thickness difference (t_{S1}−t_{S2}) of the spacer may gently vary near a phase-shifted (PS) point (λ/4 phase shift). In other embodiments, the thickness difference (t_{S1}−t_{S2}) of the grating layer may rapidly vary near the phase-shifted (PS) point (λ/4 phase shift).

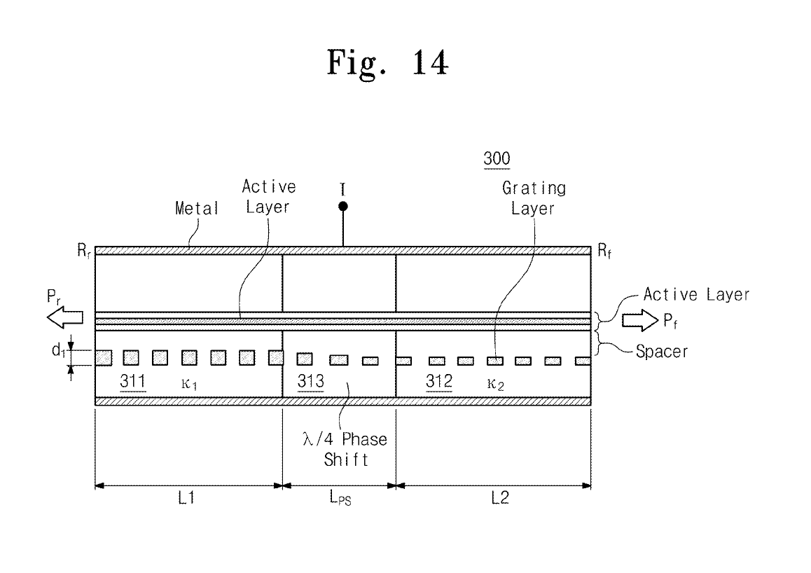

FIG. 14 is a cross-sectional view of an ACC DFB-LD 300 according to a third embodiment of the inventive concept. In the ACC DFB-LD 300, a thickness d₁ of a grating layer is made different depending on areas. Additionally, instead of a structure where a diffraction grating is directly phase-shifted, an effective refractive index n_{eff}_{_{—}}ₚ of a waveguide is made different depending on the areas such that λ/4 phase shift occurs relative to an operation wavelength throughout a phase-shifted area (third area) 313 corresponding to a predetermined length Lₚₛ. The effective refractive index n_{eff}_{_{—}}ₚ may be varied by changing a wavelength structure (width and shape). In some embodiments, a thickness of a grating layer or a spacer may gently or rapidly vary in a longitudinal direction (cavity length direction).

In the ACC DFB-LD 300, the shape of a diffraction grating is not changed in the entire cavity. Therefore, a diffraction grating may be formed using a low-cost apparatus for forming a diffraction grating (e.g., an apparatus for forming a diffraction grating through two-beam interference) instead of an E-beam device.

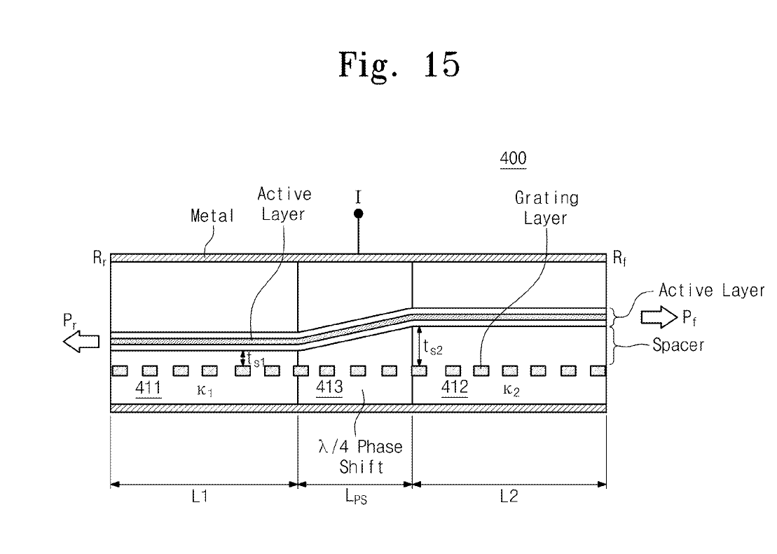

FIG. 15 is a cross-sectional view of an ACC DFB-LD 400 according to a fourth embodiment of the inventive concept. In the ACC DFB-LD 400, spacer thicknesses tₛ₁ and tₛ₂ are different depending on areas in a longitudinal direction. Additionally, an effective refractive index n_{eff}_{_{—}}ₚ of a waveguide is made different depending on the areas such that λ/4 phase shift occurs relative to an operation wavelength throughout a phase-shifted area of a length Lₚₛ. The effective refractive index n_{eff}_{_{—}}ₚ may be varied by changing a wavelength structure (width and shape). In some embodiments, a thickness of a grating layer or a spacer may gently or rapidly vary in the longitudinal direction.

To sum up, according to the above-described embodiments (first to fourth embodiments) of the inventive concept, a grating layer thickness d and a spacer thickness tₛ are structurally made different depending on areas in a longitudinal direction. Thus, an asymmetric coupling coefficient λ/4 phase-shifted distributed feedback laser diode (ACC λ/4 PS DFB-LD) may be implemented.

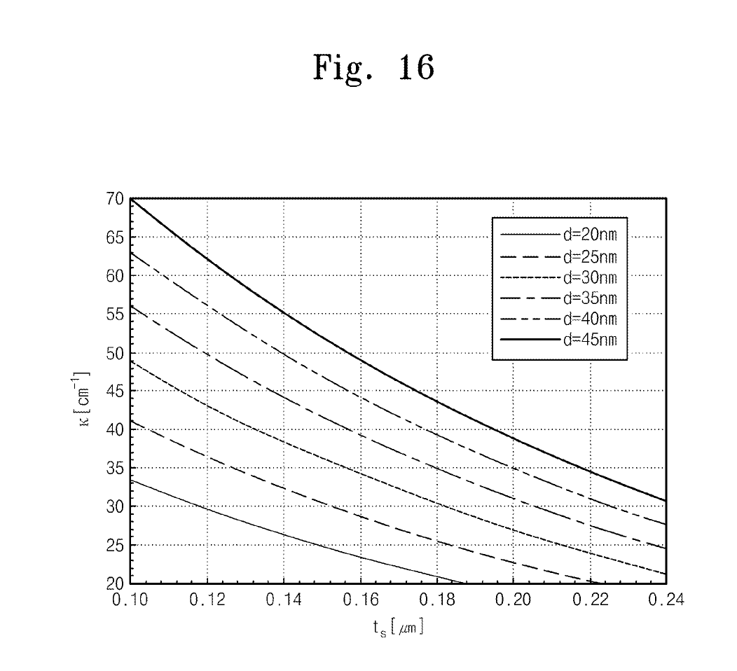

FIG. 16 is a graphic diagram illustrating an analysis result of a grating coupling coefficient, depending on change in a grating layer thickness and change in a spacer thickness, relative to a grating layer material structure that is an InGaAsP structure (bandgap wavelength=1.15 μm) and a spacer layer material structure that is an InP material structure, in the form of a ridge waveguide (RWG) which includes a multi-quantum well (MQW) structure where a gain wavelength peak of an active layer is 1300 nm in the InGaAsP material structure and has a width of 2.2 μm.

The analysis result for the detailed description will be described below with reference to examples.

A coupling coefficient of 50 cm⁻¹ is required to obtain a normalized coupling coefficient of 2 in a structure where a cavity length L is 400 μm. As shown in FIG. 16, a spacer thickness ts of about 0.12 μm may be obtained when a grating layer thickness d is 35 nm; the spacer thickness ts of about 0.14 μm may be obtained when the grating layer thickness d is 40 nm; and the spacer thickness ts of about 0.157 μm may be obtained when the grating layer thickness d is 45 nm Change in the spacer thickness ts for obtaining a coupling coefficient required with the change in grating layer thickness d was roughly linearly exhibited.

When a normalized coupling coefficient κ₁L of a first area is 2 in a structure where a cavity length L is 400 μm, a coupling coefficient ratio r_{κ} of about 0.6 is required to obtain maximum ΔαₜₕL. Therefore, a normalized coupling coefficient κ₂L of a second area is implemented near 1.2 (κ₂=30 cm⁻¹).

In terms of implementation, two cases will be described below mores specifically. Similar to the first embodiment (100 in FIG. 12) and the third embodiment (300 in FIG. 14), a first case is that a grating layer thickness d is made different depending areas. Similar to the second embodiment (200 in FIG. 13) and the fourth embodiment (400 in FIG. 15), a second case is that a spacer thickness is made different depending areas.

In the first case, when a spacer thickness is 0.12 μm, a grating layer thickness d₁ in a first area may be designed to be about 35 nm and a grating layer thickness d₂ in a second area may be designed to be 20 nm. In this case, a thickness ratio depending on respective areas (a ratio of a grating layer thickness in a second area to a grating layer thickness in a first area) is about 1.75 times.

In the second case, when a grating thickness d is 35 nm, a spacer thickness tₛ₁ in a first area may be designed to be about 0.12 μm and a spacer thickness tₛ₂ in a second area may be designed to be about 0.205 μm. In this case, a thickness ratio depending on respective areas (a ratio of a grating layer thickness in a first area to a grating layer thickness in a second area) is about 1.7 times.

As described above, to implement an ACC DFB-LD, a grating layer thickness difference (d₁−d₂) is 15 nm in the first and third embodiments and a spacer thickness difference (tₛ₂−tₛ₁) is 0.085 μm (85 nm) in the second and fourth embodiments. In addition, very precise thickness adjustment is required.

In the above description, the detailed numerical values are variable depending on a material structure of an active layer, an operation wavelength, a waveguide structure, and a material structure of a grating layer. However, the requirement for very precise thickness adjustment is effective in implementing a design method and an asymmetric coupling coefficient (ACC) structure.

For readily implementing the ACC structure, the inventive concept may introduce a selective area growth (SAG) method. According to the SAG method, a material is grown after pattering an insulating layer such as oxide (SiO₂) or nitride (SiNₓ) on a wafer surface in a metal organic chemical vapor deposition (MOCVD) equipment that is a growth equipment. Since the material is not grown on a surface of the insulating layer, III group materials (In, Ga, and Al) that are precursors migrate to a portion where there is no insulating layer and a V group material and a precursor actively react to each other at a portion between portions where there is no insulating layer. Thus, the amount decreases and the increase in concentration is caused by diffusion occurs to make the grown material thick at a portion between the insulating layers. The SAG method allows the thickness of the grown material to be adjusted through design of an insulating pattern.

As disclosed in “Mask Pattern Interference in AlGaInAs Selective Area Metal-Organic Vapor-Phase Epitaxy: Experimental and Modeling Analysis” (JOURNAL OF APPLIED PHYSICS 103, 113113 2008) by N. Dupuis et al., the SAG method may be verified by solving a Laplace equation with appropriate boundary conditions.

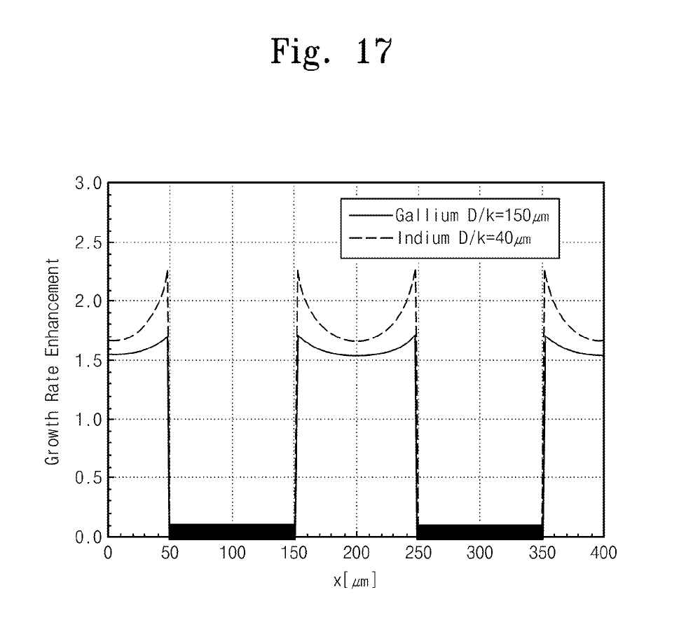

FIG. 17 is a graphic diagram of an analysis result of growth rate enhancement (compared with growth rate enhancement of an unmasked area) obtained by solving a Laplace equation to indium (In, a normalized diffusion coefficient D/k=40 μm) and gallium (Ga, a normalized diffusion coefficient D/k=150 μm), which are III group materials, using a mask having a width of 100 μm when a width of an open area is 100 μm.

In an InGaAsP material, indium (In) and gallium (Ga) each have an influence on growth rate enhancement and the influence degree of In and Ga vary depending on the composition of the grown material. Generally, it is reported that a normalized diffusion coefficient of Ga is 36-40 μm and a normalized diffusion coefficient of In is 100-150 μm (a diffusion coefficient of In of an InP material is 150 μm, a diffusion coefficient of In of InGaAsP material with a bandgap wavelength of 1.15 μm is 150 μm, a diffusion coefficient of In of InGaAsP with a bandgap wavelength of 1.2 μm, and a diffusion coefficient of In of InGaAsP with a bandgap wavelength of 1.36 μm is 115 μm).

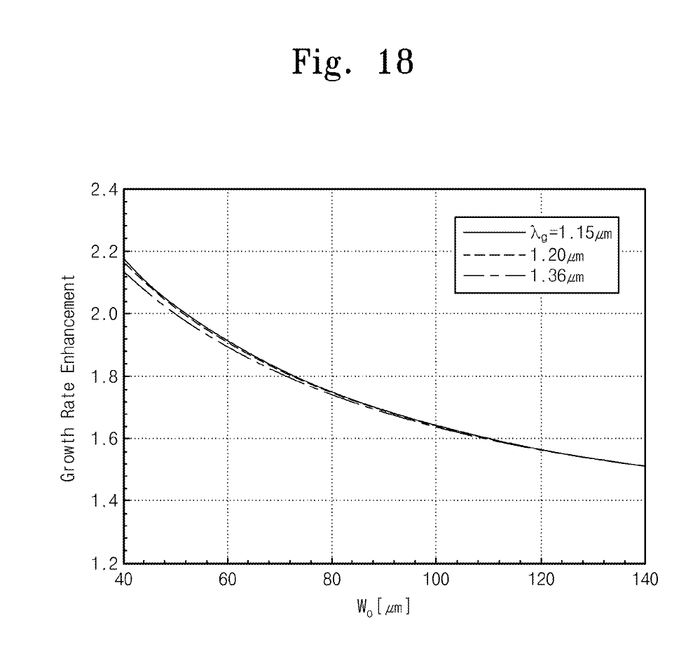

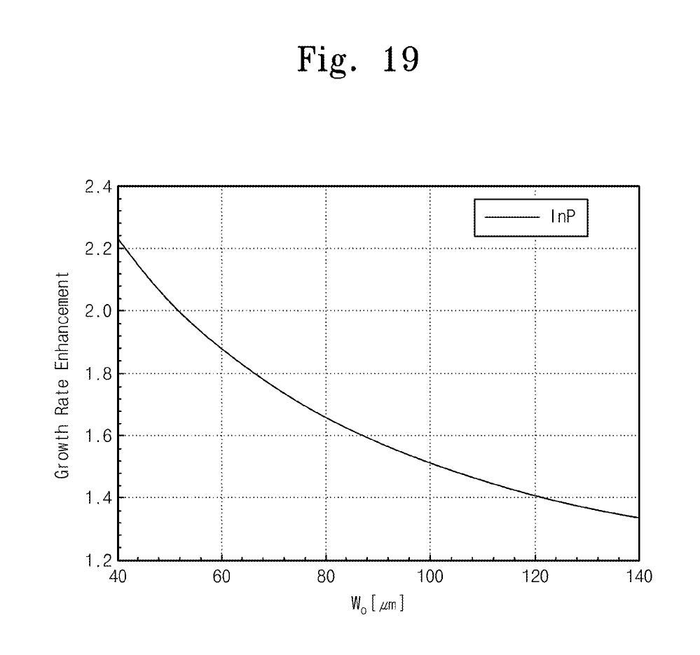

FIGS. 18 and 19 are graphic diagrams illustrating analysis results of growth rate enhancements when bandgap wavelengths λ_{g} of an InGaAsP material relative to a mask having a width of 100 μm are 1.15 μm, 1.2 μm, and 1.36 μm depending on change in width Wo of an open area relative to an InP material.

If the results in FIG. 18 are applied to the first and third embodiments, about 1.7 to 1.8 times growth rate enhancement is required. Therefore, it could be understood that suitable width Wo of an open area is 80 μm.

If the results in FIG. 18 are applied to the second and fourth embodiments, about 1.7 times growth rate enhancement is required. Therefore, it could be understood that the most suitable width Wo of an open area is 80 μm.

In embodiments of the inventive concept, as described above, change of a grating layer thickness and change of a spacer thickness may be done by adjusting width Wo of an open area or adjusting width of a mask. Moreover, the change degree of a boundary portion between a first area and a second area may be rapid through rapid change in width of the mask or may be gentle through tapering of the mask.

A method for manufacturing an asymmetric coupling coefficient distributed feedback laser diode (ACC DFB-LD) according to the embodiments of the inventive concept described with reference to FIGS. 12 to 15 is very simple.

According to the first and third embodiments described with reference to FIGS. 12 and 14, a grating thickness is made different depending on areas by a selective area growth (SAG) method. After removing an insulating layer, a diffraction grating is formed by a conventional process. A spacer layer, an active layer, a p-clad layer, and a p-InGaAs ohmic layer are sequentially grown. Since a step caused by the grating thickness difference depending on areas is very small during the growth of the spacer layer, planarization is naturally achieved. Afterwards, if a ridge waveguide process and a metal process are performed, a laser diode device is completed.

According to the second and fourth embodiments described with reference to FIGS. 13 and 15, a diffraction grating is formed first. After a spacer layer InP is grown to be different in thickness depending on areas by means of a selective area growth (SAG) method, an insulating mask is removed. An active layer, a p-clad layer, and a p-InGaAs ohmic layer are sequentially grown. A ridge process is performed.

An asymmetric coupling coefficient distributed feedback laser diode (ACC DBF-LD) according to an embodiment of the inventive concept exhibits optimized single mode performance when a coupling coefficient r, in each area is implemented to be near 0.6. In this case, about double the optical output ratio may be obtained.

Additionally, the coupling coefficient ratio in each area is implemented to be 0.5 (ΔαₜₕL=0.3) to increase an additional optical output. Thus, about three times the optical output ratio may be obtained.

Additionally, using an SAG method relative to the foregoing design result, a grating layer thickness or a spacer thickness is made different depending on areas to implement a diffraction grating having a coupling coefficient varying depending on the areas.

Through the foregoing asymmetric coupling coefficient (ACC) structure and its implementing method, precise thickness adjustment and shape design in each area may be conducted only using an SAG mask pattern. Thus, an additional process is not required and a problem does not occur. For this reason, high manufacturing yield may be secured. Moreover, the ACC structure may be implemented in the form of a diffraction grating with the same period and shape. Thus, the ACC structure may be implemented by means of a low-cost diffraction grating apparatus.

As described so far, a distributed feedback laser diode includes grating layers each having an asymmetric coefficient and is implemented within an optimal range capable of obtaining both a high front facet output and stable single mode characteristics. Thus, high manufacturing yield and low manufacturing cost can be achieved.

While the inventive concept has been particularly shown and described with reference to exemplary embodiments thereof, it will be apparent to those of ordinary skill in the art that various changes in form and detail may be made therein without departing from the spirit and scope of the inventive concept as defined by the following claims.

What is claimed is:

1. A distributed feedback laser diode comprising:
a first area having a first grating layer disposed in a longitudinal direction;
a second area disposed adjacent to the first area and having a second grating layer disposed in the longitudinal direction; and
an active layer disposed over the first and second areas,
wherein coupling coefficients of the first and second grating layers are made different in the first and second areas by a selective area growth method.

2. The distributed feedback laser diode of claim 1, wherein a phase of a diffraction grating is shifted by a quarter of an operation wavelength to perform a single longitudinal mode operation.

3. The distributed feedback laser diode of claim 2, further comprising:
a phase-shifted area formed between the first and second areas in the longitudinal direction to shift the phase of the diffraction grating by a quarter of the operation wavelength.

4. The distributed feedback laser diode of claim 2, wherein the phase of the diffraction grating is shifted by a quarter of the operation wavelength at a facet adjacent to the first and second areas.

5. The distributed feedback laser diode of claim 4, wherein thicknesses the first and second grating layers are different from each other.

6. The distributed feedback laser diode of claim 5, wherein a ratio of the thicknesses of the first and second grating layers rapidly varies above 1.7 times at the adjacent facet.

7. The distributed feedback laser diode of claim 5, wherein a ratio of the thicknesses of the first and second grating layers gently varies below 1.7 times at the adjacent facet.

8. The distributed feedback laser diode of claim 5, wherein a thickness between the active layer and the first grating layer is different from that between the active layer and the second grating layer.

9. The distributed feedback laser diode of claim 1, wherein lengths of the first and second areas are equal to each other in the longitudinal direction, and the first and second grating layers have the same grating shape.

10. The distributed feedback laser diode of claim 1, wherein a ratio of a coupling coefficient of the second grating layer to a coupling coefficient of the first grating layer ranges from 0.6 to 1.

11. The distributed feedback laser diode of claim 1, wherein the first area has a first facet differing from the facet adjacent to the first and second areas, and
which further comprises a high reflection layer coated on the first facet of the first area.

12. The distributed feedback laser diode of claim 11, wherein the second area has a second facet differing from the adjacent facet, and
which further comprises an anti-reflection layer coated on the second facet of the second area.

13. A method for manufacturing a distributed feedback laser diode, comprising:
forming a first grating layer and a second grating layer by a selective area growth method;
forming a spacer layer on the first and second grating layers;
forming a clad layer on the spacer layer; and
forming an ohmic layer on the clad layer,
wherein the first and second grating layers are disposed adjacent to each other and have different coupling coefficients.

14. The method of claim 13, wherein the forming of the first and second grating layers comprises:
making thicknesses of the first and second grating layers different from each other.

15. The method of claim 14, wherein the thicknesses of the first and second grating layers are varied by adjusting a width of an open area at a mask.

16. The method of claim 14, wherein the thicknesses of the first and second grating layers are varied by adjusting a width of a mask.

17. The method of claim 13, wherein the forming of the spacer layer comprises:
making a thickness between the first grating layer and the active layer and a thickness between the second grating layer and the active layer different from each other.

18. The method of claim 13, wherein a width of a mask is adjusted to rapidly vary coupling coefficients of the first and second grating layers.

19. The method of claim 13, wherein a mask is tapered to gently vary coupling coefficients of the first and second grating layers.

20. The method of claim 13, further comprising after forming an ohmic layer:
forming a ridge waveguide.
